(19) United States
(12) Patent Application Publication
(10) Pub. No.: US 2026/0068074 A1
(43) Pub. Date: Mar. 5, 2026

(54) NETWORK SECURITY APPLIANCE BASED ON REDUNDANT POWER SUPPLY

(71) Applicants: YUNNAN UNITED POWER DEVELOPMENT CO., LTD., Kunming (CN); HUANENG LANCANG RIVER HYDROPOWER INC., Kunming (CN)

(72) Inventors: Peng LIN, Kunming (CN); Lin FENG, Kunming (CN); Yuchen DENG, Kunming (CN); Yuyu WANG, Kunming (CN); Songtao ZHAO, Kunming (CN); Longsheng ZHANG, Kunming (CN); Xu FAN, Kunming (CN); Lihan SU, Kunming (CN); Deya QIAN, Kunming (CN); Ruizhen ZHAO, Kunming (CN); Xiaoqing YANG, Kunming (CN); Lingwen ZI, Kunming (CN)

(73) Assignees: YUNNAN UNITED POWER DEVELOPMENT CO., LTD., Kunming (CN); HUANENG LANCANG RIVER HYDROPOWER INC., Kunming (CN)

(21) Appl. No.: 18/930,489

(22) Filed: Oct. 29, 2024

(30) Foreign Application Priority Data
Aug. 27, 2024 (CN) 202411184081.5

(51) Int. Cl. H05K 7/20; H05K 5/02

(52) U.S. Cl. CPC H05K 7/20136; H05K 5/0213

(57) ABSTRACT

A network security appliance based on a redundant power supply, including a cabinet, where a redundant power supply is fixedly mounted at a bottom part of a left side of an inner wall of the cabinet, two rings are fixed to a front side of an outer wall of the redundant power supply, an electric telescopic rod is fixedly mounted on inner walls of the rings, a rectangular rod is fixed to a top surface of a telescopic end of the electric telescopic rod, several vertical columns are fixed to a top surface of the rectangular rod, a cover plate is fixed to a top surface of the cabinet, the cover plate is provided with several rectangular slots, and a strip-shaped plate is rotatably mounted on a left or right side of an inner wall of the rectangular slot of the cover plate.

### TECHNICAL FIELD

The present invention relates to the technical field of network security appliances, in particular to a network security appliance based on a redundant power supply.

### BACKGROUND ART

A network security appliance based on a redundant power supply uses two identical power supplies, and a chip controls the power supplies for load balancing, so that when one power supply fails, the other power supply can immediately take over its work. After the power supply in failure is repaired, the two power supplies work together, thereby ensuring that the network security appliance can still work normally when one power supply is accidentally damaged.

The patent with the patent number of CN203722325U discloses a network security appliance based on a redundant power supply, which includes a front panel, two side panels, an upper panel, a lower panel, and a rear panel, wherein the upper panel is connected to the two side panels by screws, the rear panel is connected to the upper panel by screws, and the front panel is connected to the upper panel and the lower panel by snap structures; the upper panel is provided with an device nameplate; the front panel is provided with indicators and indicator nameplates; and the two side panels are each provided with an anti-slip convex portion. The patent is simple in structure and easy to disassemble and assemble. The use of each power supply can be shown by a corresponding power indicator, so that the maintenance efficiency can be improved when a certain power supply fails; the anti-slip convex portions are arranged, and each anti-slip convex portion is in the shape of a long strip, thereby enhancing the anti-slip effect of the network security appliance.

However, the current network security appliance based on a redundant power supply has the following problems: in use of the network security appliance based on a redundant power supply, when one power supply in the redundant power supply is damaged, and the other power supply is used for loading all the electric power, the power consumption of the other power supply increases, and its heat rises continuously, which can easily cause overheated damage to the redundant power supply, and consequently the problem that when one power supply in the redundant power supply is damaged, the power of the other power supply is too high, a temperature rise is caused, and the network security appliance is damaged is caused. Therefore, a new network security appliance based on a redundant power supply is provided.

### SUMMARY OF THE INVENTION

Directing at the defects in the prior art, the present invention provides a network security appliance based on a redundant power supply, which solves the above problems mentioned in the background art.

In order to achieve the above-mentioned purposes, the present invention is implemented through the following technical solution: a network security appliance based on a redundant power supply, including a cabinet, a redundant power supply being fixedly mounted at a bottom part of a left side of an inner wall of the cabinet, a mainboard being fixedly mounted on a front side of the inner wall of the cabinet, and two electric fans being fixedly mounted at a bottom end inside the cabinet, where two rings are fixed to a front side of an outer wall of the redundant power supply, an electric telescopic rod is fixedly mounted on inner walls of the rings, a rectangular rod is fixed to a top surface of a telescopic end of the electric telescopic rod, several vertical columns are fixed to a top surface of the rectangular rod, a cover plate is fixed to a top surface of the cabinet, a top surface of the cover plate is provided with several exhaust holes, the cover plate is provided with several rectangular slots, a strip-shaped plate is rotatably mounted on a left or right side of an inner wall of each rectangular slot of the cover plate, a first torsional spring is arranged between each strip-shaped plate and the cover plate, each strip-shaped plate is located on a movement trajectory of a corresponding vertical column, under the action of an extruding force, each strip-shaped plate is rotated upwards in the corresponding rectangular slot of the cover plate so that the rectangular slot is opened by the cover plate, and the electric fans discharge heat accumulated in the cabinet upwards;
each vertical column is provided with a chamber inside;
a warning assembly is disposed inside each vertical column, the warning assembly includes a conductive block, the conductive block is fixed to a bottom end of an inner wall of the vertical column, the conductive block is connected to a wire of the redundant power supply, a rubber column is slidably mounted on the inner wall of the vertical column, a first spring is arranged between the rubber column and the conductive block, an LED lamp is fixedly mounted on a top surface of the rubber column, a conductive rod penetrates through and is fixedly mounted on a bottom surface of the rubber column, the conductive rod is fixedly connected to the LED lamp, the LED lamp flickers while the device dissipates heat, so that the flickering LED lamp is obvious to staff, a heat accumulation prevention device is coupled to a top surface of the rectangular rod, and a fire prevention device is coupled to a bottom surface of the rectangular rod.

According to the above-mentioned technical solution, four supporting legs are disposed on a bottom surface of the cabinet, a rectangular opening is formed at a bottom part of a front side of the cabinet, a cabinet door is hinged to a right part of the front side of the cabinet, bottom parts of left and right sides of the cabinet are provided with heat dissipation openings, the bottom part of the left side of the cabinet is provided with a power supply interface, and the bottom surface of the cabinet is provided with two air intake slots.

According to the above-mentioned technical solution, the heat accumulation prevention device includes a cross bar, the cross bar is fixed to the top surface of the rectangular rod, an opposite end of the cross bar penetrates through a fan plate and the fan plate is rotatably mounted on the cross bar, the fan plate is disposed in a middle part inside the cabinet, rollers are fixed to a rotating shaft of the fan plate at both ends thereof, two U-shaped frames are fixed to a right side of the inner wall of the cabinet, each U-shaped frame is disposed on a left side of a corresponding roller, under the action of a friction force, each roller rolls back and forth vertically on a corresponding U-shaped frame, and the roller drives the fan plate to rotate back and forth forwards and reversely, so that the fan plate fans heat accumulated on the redundant power supply and allows the heat to be discharged upwards more quickly.

According to the above-mentioned technical solution, an outer wall of the fan plate is covered with anti-static coating, an outer wall of each roller is provided with a rubber rough surface, a middle part of a right side of each U-shaped frame is provided with a penetration opening, and a wheel width of the roller is greater than a width of the penetration opening of the U-shaped frame.

According to the above-mentioned technical solution, the heat accumulation prevention device further includes a half-arc block, the half-arc block is fixed to a left side of an inner wall of each U-shaped frame, an arc-shaped spring plate is fixed to an opposite face of the half-arc block, the arc-shaped spring plate penetrates through the penetration opening of the U-shaped frame, a slidable rod is fixed to a left side of the arc-shaped spring plate, a vertical strip plate is fixed to the inner wall of the U-shaped frame, the slidable rod penetrates through and is slidably connected to the vertical strip plate, a dehumidifying box is fixed to a left side of the slidable rod, and the slidable rod drives the dehumidifying box to move back and forth horizontally, so that the dehumidifying box makes large-area contact with gas in the cabinet when being moved back and forth horizontally, thereby improving the dehumidifying effect of the dehumidifying box.

According to the above-mentioned technical solution, the fire prevention device includes a connection plate, the connection plate is fixed to the bottom surface of the rectangular rod, an inclined rod is hinged to a front side of the connection plate, a U-shaped sliding groove is fixed to a right side of the inner wall of the cabinet, front and back sides of the U-shaped sliding groove are each provided with a sliding groove, rubber wheels are rotatably mounted at bottoms of front and back sides of the inclined rod, each rubber wheel is rotatably mounted on an inner wall of a corresponding sliding groove of the U-shaped sliding groove, a carbon dioxide cartridge is fixedly mounted at a bottom end inside the cabinet, three hoses penetrate through and are fixedly disposed on a top surface of the carbon dioxide cartridge, three electric spray nozzles penetrate through and are fixedly mounted on a back side of the inclined rod, each electric spray nozzle is fixedly connected to a corresponding hose of the carbon dioxide cartridge, and the inclined rod drives the electric spray nozzle to swing for spraying carbon dioxide out, so that the cabinet can be more uniformly filled with the carbon dioxide.

According to the above-mentioned technical solution, a second torsional spring is arranged between the inclined rod and the connection plate, a temperature sensor is mounted on a back side of the inclined rod, the U-shaped sliding groove is located on a lower portion inside the cabinet, the connection plate is located on a front side of the electric telescopic rod, and a bottom part of a right side of the inclined rod is provided with a chamber.

According to the above-mentioned technical solution, the fire prevention device further includes a short plate, the short plate is rotatably mounted on an upper portion of an inner wall of the chamber of the inclined rod, a rectangular box is fixed to a right side of the short plate, a long plate is slidably mounted on an inner wall of the rectangular box, a second spring is arranged between the long plate and the rectangular box, the long plate is rotatably mounted on a right side of an inner wall of the U-shaped sliding groove, a rotating shaft of the long plate is located on a movement trajectory of the inclined rod, and the inclined rod transmits vibration onto each electric spray nozzle so that the electric spray nozzle is vibrated for spraying the carbon dioxide out.

The present invention provides a network security appliance based on a redundant power supply, which has the following beneficial effects.
(1) The present invention uses the ring, the electric telescopic rod, the rectangular rod, the vertical column, the cover plate, the strip-shaped plate, the conductive block, the rubber column and the LED lamp to cooperate with the conductive rod; when the vertical column is moved upwards, the vertical column is upwardly pressed against the strip-shaped plate, and the strip-shaped plate is rotated upwards in the rectangular slot of the cover plate under the action of the extruding force; the first torsional spring on the strip-shaped plate is contracted under the action of an elastic force; when the vertical column is moved downwards and leaves the strip-shaped plate, under the action of the elastic force of the first torsional spring, the strip-shaped plate resets, so that the rectangular slot is opened by the cover plate, and the electric fan discharges the heat accumulated in the cabinet upwards, thereby preventing the problem that when the redundant power supply of the network security appliance is damaged, a temperature rise is caused by too high power, and consequently the network security appliance is damaged; the rubber column drives the conductive rod to move downwards, and the conductive rod is moved downwards and makes contact with the conductive block; the conductive rod transmits electric power to the LED lamp, and the LED lamp is on; and when the LED lamp is moved downwards and leaves the strip-shaped plate, the rubber column resets, so that the LED lamp flickers when the device dissipates heat, and the flickering LED lamp is obvious to staff, thereby preventing the problem that it is inconvenient to immediately find damage to the redundant power supply of the network security appliance, and consequently load time of the redundant power supply is too long.
(2) In the present invention, by arranging the heat accumulation prevention device, the cross bar, the fan plate, the roller, the U-shaped frame, the half-arc block, the arc-shaped spring plate, the slidable rod and the vertical strip plate cooperate with the dehumidifying box; under the action of the friction force, the roller rolls back and forth vertically on the U-shaped frame, the roller drives the fan plate to rotate back and forth forwards and reversely, so that the fan plate fans heat accumulated on the redundant power supply, and the heat is discharged upwards more quickly, thereby preventing the problem that when the heat accumulated on the redundant power supply of the network security appliance is too high, the redundant power supply burns out, resulting in a short circuit of the network security appliance; and the slidable rod is moved back and forth horizontally in the vertical strip plate, and the slidable rod drives the dehumidifying box to move back and forth horizontally, so that the dehumidifying box makes large-area contact with the gas in the cabinet when being moved back and forth horizontally, thereby improving the dehumidifying effect of the dehumidifying box, and preventing the problem that when the redundant power supply of the network security appliance is damaged, a large amount of moisture enters the cabinet, and consequently the device is seriously affected with damp.
(3) In the present invention, by arranging the fire prevention device, the connection plate, the inclined rod, the U-shaped sliding groove, the rubber wheel, the carbon dioxide cartridge, the electric spray nozzle, the short plate and the rectangular box cooperate with the long plate; under the action of the friction force, the rubber wheel rolls in the sliding groove of the U-shaped sliding groove, so that the inclined rod is made to swing back and forth horizontally, the electric spray nozzle sprays the carbon dioxide out, the inclined rod drives the electric spray nozzle to swing for spraying the carbon dioxide out, and the cabinet is more uniformly filled with the carbon dioxide, thereby preventing the problem that the network security appliance is on fire when a load is too high, and blocking fire is not timely; and the inclined rod can knock a rotating shaft of the long plate, the inclined rod can produce a certain degree of vibration, so that the inclined rod transmits the vibration onto the electric spray nozzle, and the electric spray nozzle is made to vibrate to spray the carbon dioxide out, thereby preventing the problem that when the fire prevention device of the network security appliance is not used for a long time, the electric spray nozzle is blocked by impurities, and consequently blocking fire spreading is not timely.

### BRIEF DESCRIPTION OF DRAWINGS

FIG. 1 is an overall schematic view of the present invention;

FIG. 2 is an overall unfolded schematic view of the present invention;

FIG. 3 is an overall sectional view of the present invention;

FIG. 4 is a sectional view of a ring of the present invention;

FIG. 5 is a partially enlarged schematic view of position A of the ring of the present invention;

FIG. 6 is a sectional view of a heat accumulation prevention device of the present invention;

FIG. 7 is a partially enlarged schematic view of position B of the heat accumulation prevention device of the present invention;

FIG. 8 is a sectional view of a fire prevention device of the present invention; and

FIG. 9 is a partially enlarged schematic view of position C of the fire prevention device of the present invention.

In the drawings: 1, cabinet; 2, redundant power supply; 3, mainboard; 4, electric fan; 5, ring; 6, heat accumulation prevention device; 61, cross bar; 62, fan plate; 63, roller; 64, U-shaped frame; 65, half-arc block; 66, arc-shaped spring plate; 67, slidable rod; 68, vertical strip plate; 69, dehumidifying box; 7, fire prevention device; 71, connection plate; 72 [symbol] inclined rod; 73, U-shaped sliding groove; 74, rubber wheel; 75, carbon dioxide cartridge; 76, electric spray nozzle; 77, short plate; 78, rectangular box; 79, long plate; 8, electric telescopic rod; 9, rectangular rod; 10, vertical column; 11, cover plate; 12, strip-shaped plate; 13, conductive block; 14, rubber column; 15, LED lamp; 16, conductive rod.

### DETAILED DESCRIPTION

The technical solutions in embodiments of the present invention will be clearly and completely described below with reference to the accompanying drawings in the embodiments of the present invention. Apparently, the described embodiments are merely some rather than all of the embodiments of the present invention.

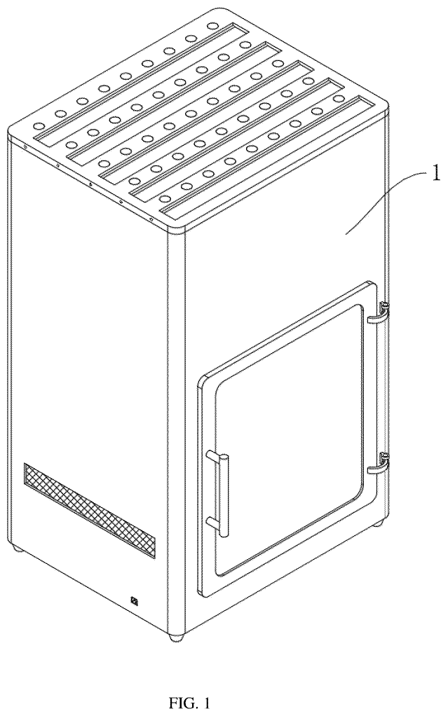

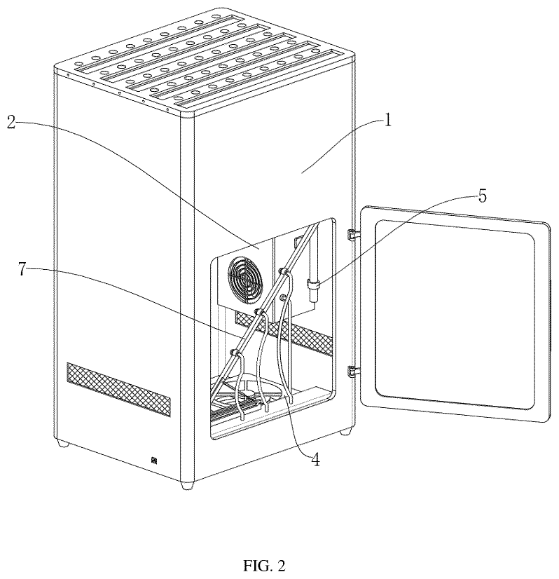

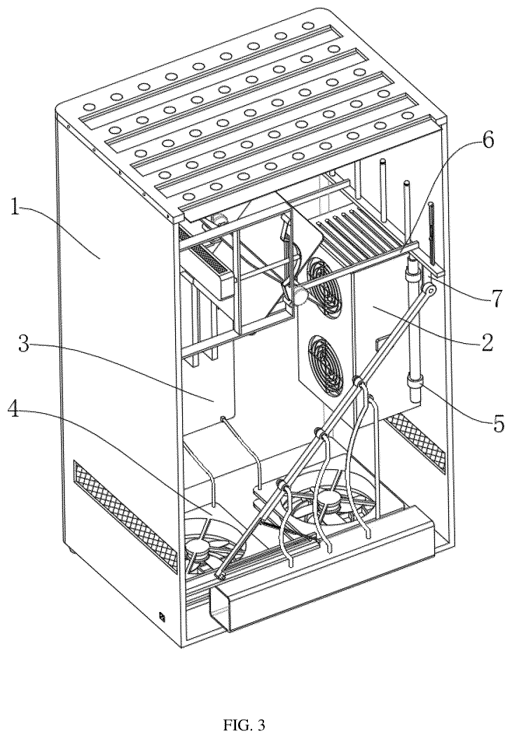

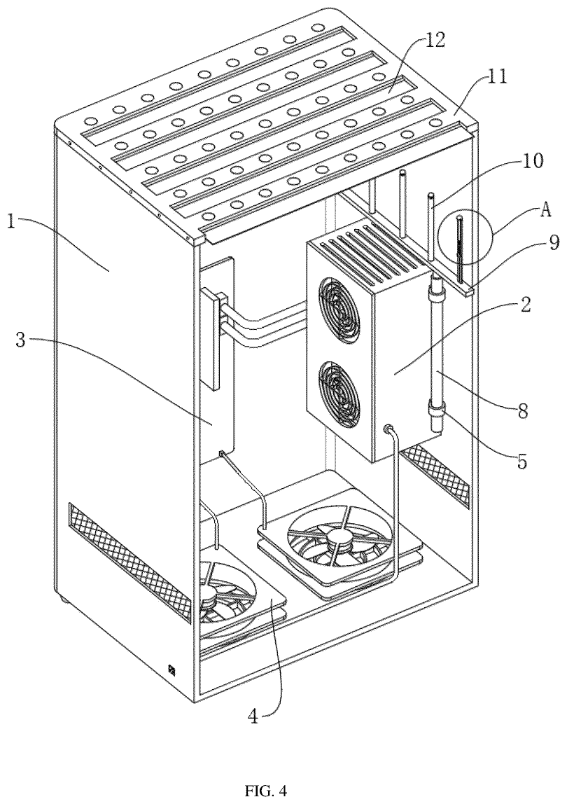

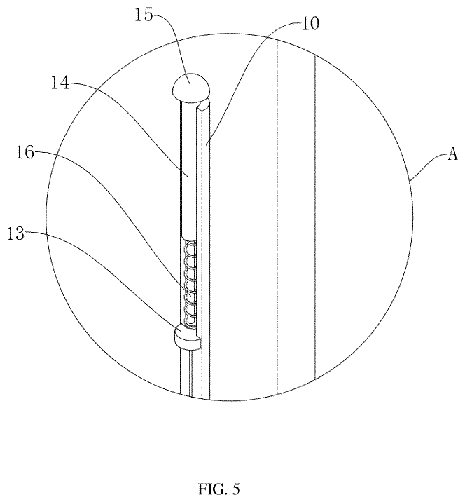

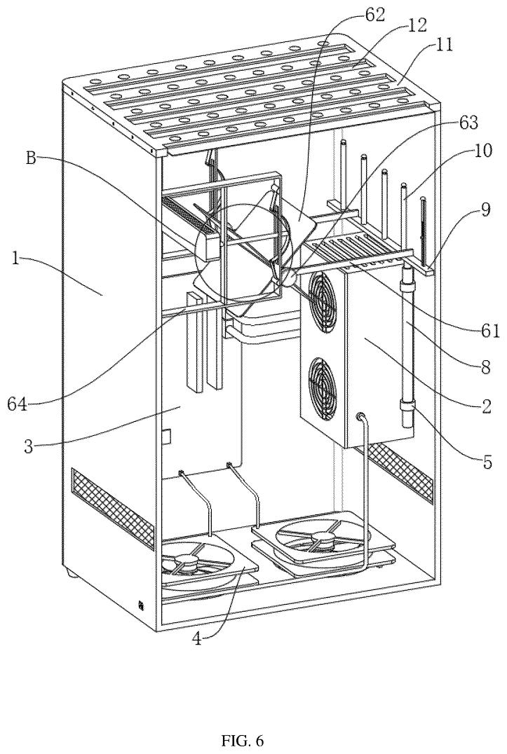

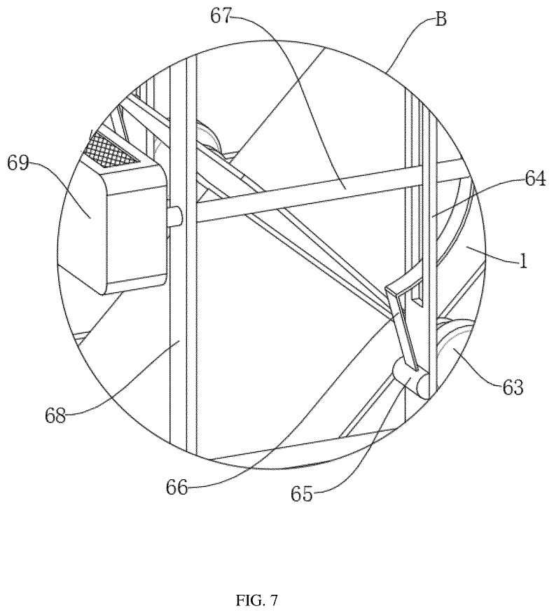

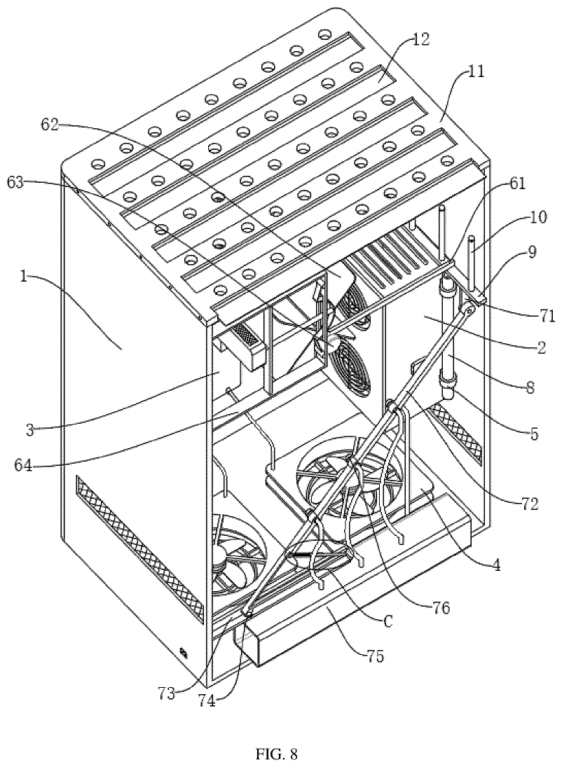

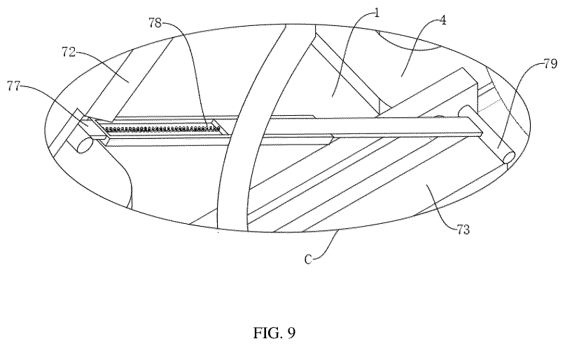

Please refer to FIG. 1 to FIG. 9, an embodiment of the present invention is a network security appliance based on a redundant power supply, including a cabinet 1, where a redundant power supply 2 is fixedly mounted at a bottom part of a left side of an inner wall of the cabinet 1, a mainboard 3 is fixedly mounted on a front side of the inner wall of the cabinet 1, two electric fans 4 are fixedly mounted at a bottom end inside the cabinet 1, two rings 5 are fixed to a front side of an outer wall of the redundant power supply 2, an electric telescopic rod 8 is fixedly mounted on inner walls of the rings 5, a rectangular rod 9 is fixed to a top surface of a telescopic end of the electric telescopic rod 8, several vertical columns 10 are fixed to a top surface of the rectangular rod 9, a cover plate 11 is fixed to a top surface of the cabinet 1, a top surface of the cover plate 11 is provided with several exhaust holes, the cover plate 11 is provided with several rectangular slots, a strip-shaped plate 12 is rotatably mounted on a left or right side of an inner wall of each rectangular slot of the cover plate 11, a first torsional spring is arranged between each strip-shaped plate 12 and the cover plate 11, each strip-shaped plate 12 is located on a movement trajectory of a corresponding vertical column 10, each strip-shaped plate 12 is rotated upwards in the corresponding rectangular slot of the cover plate 11 so that the rectangular slot is opened by the cover plate 11, and the electric fans 4 discharge heat accumulated in the cabinet 1 upwards, thereby avoiding the problem that when the redundant power supply 2 of the network security appliance is damaged, a temperature rise is caused by too high power, and consequently the network security appliance is damaged;
each vertical column 10 is provided with a chamber inside;
a warning assembly is disposed inside each vertical column 10, the warning assembly includes a conductive block 13, the conductive block 13 is fixed to a bottom end of an inner wall of the vertical column 10, the conductive block 13 is connected to a wire of the redundant power supply 2, a rubber column 14 is slidably mounted on the inner wall of the vertical column 10, a first spring is arranged between the rubber column 14 and the conductive block 13, an LED lamp 15 is fixedly mounted on a top surface of the rubber column 14, a conductive rod 16 penetrates through and is fixedly mounted on a bottom surface of the rubber column 14, the conductive rod 16 is fixedly connected to the LED lamp 15, the conductive rod 16 is moved downwards and makes contact with the conductive block 13, the conductive rod 16 transmits electric power to the LED lamp 15, and the LED lamp 15 is on. When the LED lamp 15 is moved downwards and leaves the strip-shaped plate 12, the rubber column 14 resets, so that the LED lamp 15 flickers when the device dissipates heat, and the flickering LED lamp 15 is obvious to staff, thereby avoiding the problem that it is inconvenient to immediately find damage to the redundant power supply 2 of the network security appliance, and consequently load time of the redundant power supply 2 is too long.

Four supporting legs are disposed on a bottom surface of the cabinet 1, a rectangular opening is formed at a bottom part of a front side of the cabinet 1, a cabinet door is hinged to a right part of the front side of the cabinet 1, bottom parts of left and right sides of the cabinet 1 are provided with heat dissipation openings, the bottom part of the left side of the cabinet 1 is provided with a power supply interface, and the bottom surface of the cabinet 1 is provided with two air intake slots.

In use, the staff use a wire to connect to the power supply interface of cabinet 1, the redundant power supply 2 on the cabinet 1 is powered on, the mainboard 3 is powered on by the wire of the redundant power supply 2, the mainboard 3 is started, and the mainboard 3 starts to intercept harmful information on the network to stop the harmful information on the network from threatening an Internet device. At the same time, the mainboard 3 transmits the electric power to the electric fan 4 through the wire, the electric fan 4 is started, and the electric fan 4 starts to rotate and the electric fan 4 extracts air from the air intake slot of the cabinet 1, making the device automatically air-cooled. When one power supply in the redundant power supply 2 is damaged, and the other power supply is used for loading all the electric power, the power consumption of the other power supply increases, and the heat thereof increases continuously, which is prone to cause overheated damage to the redundant power supply 2. When one power supply in the redundant power supply 2 is damaged, the rotational speed of the electric fan 4 is increased, at the same time, the redundant power supply 2 supports the ring 5, and the redundant power supply 2 starts the electric telescopic rod 8 through the wire, the telescopic end of the electric telescopic rod 8 starts to move back and forth vertically, the telescopic end of the electric telescopic rod 8 drives the rectangular rod 9 to move back and forth vertically, and the rectangular rod 9 drives the vertical column 10 to move back and forth vertically. Meanwhile, the cabinet 1 supports the cover plate 11, and the cover plate 11 supports the strip-shaped plate 12. When the vertical column 10 is moved upwards, the vertical column 10 is upwardly pressed against the strip-shaped plate 12, and the strip-shaped plate 12 is rotated upwards in the rectangular slot of the cover plate 11 under the action of the extruding force. The first torsional spring on the strip-shaped plate 12 is contracted under the action of an elastic force. When the vertical column 10 is moved downwards and leaves the strip-shaped plate 12, under the action of the elastic force of the first torsional spring, the strip-shaped plate 12 resets, so that the rectangular slot is opened by the cover plate 11, the electric fan 4 discharges the heat accumulated in the cabinet 1 upwards, and overheat of the power supply caused when the power of the redundant power supply 2 increases is prevented, thereby avoiding the problem that when the redundant power supply 2 of the network security appliance is damaged, a temperature rise is caused by too high power, and consequently the network security appliance is damaged.

When the rectangular rod 9 drives the vertical column 10 to move back and forth vertically, the vertical column 10 drives the conductive block 13 to move back and forth vertically, the conductive block 13 drives the first spring to move back and forth vertically, the first spring drives the rubber column 14 to move back and forth vertically, the rubber column 14 drives the LED lamp 15 to move back and forth vertically, and the rubber column 14 drives the conductive rod 16 to move back and forth vertically. When the rubber column 14 is moved upwards, the LED lamp 15 makes contact with the strip-shaped plate 12, the LED lamp 15 is limited by the strip-shaped plate 12, the LED lamp 15 drives the rubber column 14 to move downwards, the rubber column 14 is made to slide downwards in the chamber of the vertical column 10, the first spring on the rubber column 14 is contracted under the action of the elastic force, the rubber column 14 drives the conductive rod 16 to move downwards, the conductive rod 16 is moved downwards and makes contact with the conductive block 13, the conductive rod 16 transmits the electric power to the LED lamp 15, and the LED lamp 15 is on. When the LED lamp 15 is moved downwards and leaves the strip-shaped plate 12, the rubber column 14 resets, so that the LED lamp 15 flickers when the device dissipates heat, the flickering LED lamp 15 is obvious to the staff, and the problem that it is inconvenient for the staff to immediately find damage to the redundant power supply 2 is prevented, thereby avoiding the problem that when the redundant power supply 2 of the network security appliance is damaged, it is inconvenient to immediately find the damage, resulting in too long load time of the redundant power supply 2.

Please refer to FIG. 1 to FIG. 9, on the basis of the above-mentioned embodiment, in another embodiment of the present invention, a heat accumulation prevention device 6 and a fire prevention device 7 are further included, where the heat accumulation prevention device 6 is coupled to a top surface of the rectangular rod 9; the heat accumulation prevention device 6 comprises a cross bar 61, the cross bar 61 is fixed to the top surface of the rectangular rod 9, an opposite end of the cross bar 61 penetrates through a fan plate 62 and the fan plate 62 is rotatably mounted on the cross bar 61, the fan plate 62 is disposed in a middle part inside the cabinet 1, rollers 63 are fixed to a rotating shaft of the fan plate 62 at both ends thereof, two U-shaped frames 64 are fixed to a right side of the inner wall of the cabinet 1, and each U-shaped frame 64 is disposed on a left side of a corresponding roller 63; an outer wall of the fan plate 62 is covered with anti-static coating, an outer wall of each roller 63 is provided with a rubber rough surface, a middle part of a right side of each U-shaped frame 64 is provided with a penetration opening, and a wheel width of the roller 63 is greater than a width of the penetration opening of the U-shaped frame 64; the fan plate 62 fans the heat accumulated on the redundant power supply 2 and allows the heat to be discharged upwards more quickly, thereby avoiding the problem that when the heat accumulated on the redundant power supply 2 of the network security appliance is too high, the redundant power supply 2 burns out, resulting in a short circuit of the network security appliance.

The heat accumulation prevention device 6 further comprises a half-arc block 65, the half-arc block 65 is fixed to a left side of an inner wall of each U-shaped frame 64, an arc-shaped spring plate 66 is fixed to an opposite face of the half-arc block 65, the arc-shaped spring plate 66 penetrates through the penetration opening of the U-shaped frame 64, a slidable rod 67 is fixed to a left side of the arc-shaped spring plate 66, a vertical strip plate 68 is fixed to the inner wall of the U-shaped frame 64, the slidable rod 67 penetrates through and is slidably connected to the vertical strip plate 68, a dehumidifying box 69 is fixed to a left side of the slidable rod 67, and the dehumidifying box 69 makes large-area contact with gas in the cabinet 1 when being moved back and forth horizontally, thereby improving the dehumidifying effect of the dehumidifying box 69 and avoiding the problem that when the redundant power supply 2 of the network security appliance is damaged, a large amount of moisture enters the cabinet 1, and consequently the device is seriously affected with damp

The fire prevention device 7 is coupled to a bottom surface of the rectangular rod 9, and the fire prevention device 7 includes a connection plate 71, the connection plate 71 is fixed to the bottom surface of the rectangular rod 9, an inclined rod 72 is hinged to a front side of the connection plate 71, a U-shaped sliding groove 73 is fixed to a right side of the inner wall of the cabinet 1, front and back sides of the U-shaped sliding groove 73 are each provided with a sliding groove, rubber wheels 74 are rotatably mounted at bottoms of front and back sides of the inclined rod 72, each rubber wheel 74 is rotatably mounted on an inner wall of a corresponding sliding groove of the U-shaped sliding groove 73, a carbon dioxide cartridge 75 is fixedly mounted at a bottom end inside the cabinet 1, three hoses penetrate through and are fixedly disposed on a top surface of the carbon dioxide cartridge 75, three electric spray nozzles 76 penetrate through and are fixedly mounted on a back side of the inclined rod 72, and each electric spray nozzle 76 is fixedly connected to a corresponding hose of the carbon dioxide cartridge 75; a second torsional spring is arranged between the inclined rod 72 and the connection plate 71, a temperature sensor is mounted on a back side of the inclined rod 72, the U-shaped sliding groove 73 is located on a lower portion inside the cabinet 1, the connection plate 71 is located on a front side of the electric telescopic rod 8, a bottom part of a right side of the inclined rod 72 is provided with a chamber, and the inclined rod 72 drives the electric spray nozzle 76 to swing for spraying carbon dioxide out, so that the cabinet 1 can be more uniformly filled with the carbon dioxide, thereby avoiding the problem that when the network security appliance is on fire due to too high load, blocking fire is not timely.

The fire prevention device 7 further includes a short plate 77, the short plate 77 is rotatably mounted on an upper portion of an inner wall of the chamber of the inclined rod 72, a rectangular box 78 is fixed to a right side of the short plate 77, a long plate 79 is slidably mounted on an inner wall of the rectangular box 78, a second spring is arranged between the long plate 79 and the rectangular box 78, the long plate 79 is rotatably mounted on a right side of an inner wall of the U-shaped sliding groove 73, a rotating shaft of the long plate 79 is located on a movement trajectory of the inclined rod 72, and the inclined rod 72 transmits vibration onto each electric spray nozzle 76 so that the electric spray nozzle 76 is vibrated for spraying the carbon dioxide out, thereby avoiding the problem that when the fire prevention device 7 of the network security appliance is not used for a long time, the electric spray nozzle 76 is blocked by impurities, and consequently blocking fire spreading is not timely enough.

When the telescopic end of the electric telescopic rod 8 drives the rectangular rod 9 to move back and forth vertically, the rectangular rod 9 drives the cross bar 61 to move back and forth vertically, the cross bar 61 drives the fan plate 62 to move back and forth vertically, the fan plate 62 drives the roller 63 to move back and forth vertically, meanwhile, the cabinet 1 supports the U-shaped frame 64, under the action of the friction force, the roller 63 rolls back and forth vertically on the U-shaped frame 64, the roller 63 drives the fan plate 62 to rotate back and forth forwards and reversely, so that the fan plate 62 fans heat accumulated on the redundant power supply 2, the heat is discharged upwards more quickly, and the problem that when the heat is accumulated on the redundant power supply 2, the redundant power supply 2 burns out due to overheat is prevented, thereby avoiding the problem that when the heat accumulated on the redundant power supply 2 of the network security appliance is too high, the redundant power supply 2 burns out, resulting in a short circuit of the network security appliance.

When the roller 63 rolls back and forth vertically on the U-shaped frame 64, the U-shaped frame 64 supports the half-arc block 65, the half-arc block 65 supports the arc-shaped spring plate 66, the roller 63 makes contact with the arc-shaped spring plate 66, under the action of the extruding force and the elastic force of the arc-shaped spring plate 66, the arc-shaped spring plate 66 is deformed, the arc-shaped spring plate 66 drives the slidable rod 67 to move back and forth horizontally, the slidable rod 67 is moved back and forth horizontally in the vertical strip plate 68, the slidable rod 67 drives the dehumidifying box 69 to move back and forth horizontally, so that the dehumidifying box 69 makes large-area contact with gas in the cabinet 1 when being moved back and forth horizontally, thereby improving the dehumidifying effect of the dehumidifying box 69 and preventing the problem that in a high load mode of the network security appliance, a large amount of moisture enters and is accumulated, and thus the problem that when the redundant power supply 2 of the network security appliance is damaged, a large amount of moisture enters the cabinet 1, and consequently the device is seriously affected with damp is avoided.

When the telescopic end of the electric telescopic rod 8 drives the rectangular rod 9 to move back and forth vertically, the rectangular rod 9 drives the connection plate 71 to move back and forth vertically, the connection plate 71 drives the inclined rod 72 to move back and forth vertically, and the inclined rod 72 is limited by the U-shaped sliding groove 73. At the same time, under the action of an elastic force of the second torsional spring of the inclined rod 72, one end of the inclined rod 72 is rotated back and forth vertically on the connection plate 71, the other end of the inclined rod 72 is made to slide back and forth horizontally in the U-shaped sliding groove 73. Meanwhile, the inclined rod 72 drives the rubber wheel 74 to move back and forth horizontally. Under the action of the friction force, the rubber wheel 74 rolls in the sliding groove of the U-shaped sliding groove 73, so that the inclined rod 72 is made to swing back and forth horizontally. When the temperature sensor on the inclined rod 72 senses that the redundant power supply 2 is on fire due to an overload, the electric spray nozzle 76 on the inclined rod 72 is started. Then, compressed carbon dioxide in the carbon dioxide cartridge 75 on the cabinet 1 enters the hose, the hose conveys the carbon dioxide into the electric spray nozzle 76, the electric spray nozzle 76 sprays the carbon dioxide out so that the inclined rod 72 drives the electric spray nozzle 76 to swing for spraying the carbon dioxide out, the cabinet 1 can be more uniformly filled with the carbon dioxide, and the problem that when the device is accidentally on fire, fire spreading cannot be blocked timely is prevented, thereby avoiding the problem that when the network security appliance is on fire because the load is too high, blocking fire behavior is not timely.

When the inclined rod 72 is made to swing back and forth horizontally, the inclined rod 72 drives the short plate 77 to swing back and forth horizontally, the short plate 77 drives the rectangular box 78 to swing back and forth horizontally, the rectangular box 78 drives the long plate 79 to swing back and forth horizontally, the long plate 79 is limited by the U-shaped sliding groove 73, the long plate 79 is rotated back and forth vertically in the U-shaped sliding groove 73, the long plate 79 is made to slide back and forth vertically in the rectangular box 78, the second spring in the rectangular box 78 is contracted back and forth under the action of the elastic force, and the inclined rod 72 is made to swing more stably. When the long plate 79 is rotated to the uppermost, the inclined rod 72 can knock a rotating shaft of the long plate 79, the inclined rod 72 can produce a certain degree of vibration, so that the inclined rod 72 transmits vibration onto the electric spray nozzle 76, the electric spray nozzle 76 is vibrated to spray the carbon dioxide out, and the problem that when the fire prevention device is not used for a long time, the electric spray nozzle 76 is blocked by impurities thereon and cannot be used for spraying the carbon dioxide out is prevented, thereby avoiding the problem that when the fire prevention device 7 of the network security appliance is not used for a long time, the electric spray nozzle 76 is blocked by impurities, and consequently blocking fire spreading is not timely enough.

What is described above is only a preferred embodiment of the present invention, but the protection scope of the present invention is not limited thereto, and any equivalent substitution or improvement made by those skilled in the art within the technical scope disclosed in the present invention according to the technical solution and the inventive concept of the present invention shall fall within the protection scope of the present invention.

1. A network security appliance based on a redundant power supply, comprising a cabinet (1), a redundant power supply (2) being fixedly mounted at a bottom part of a left side of an inner wall of the cabinet (1), a mainboard (3) being fixedly mounted on a front side of the inner wall of the cabinet (1), and two electric fans (4) being fixedly mounted at a bottom end inside the cabinet (1), wherein two rings (5) are fixed to a front side of an outer wall of the redundant power supply (2), an electric telescopic rod (8) is fixedly mounted on inner walls of the rings (5), a rectangular rod (9) is fixed to a top surface of a telescopic end of the electric telescopic rod (8), several vertical columns (10) are fixed to a top surface of the rectangular rod (9), a cover plate (11) is fixed at a top surface of the cabinet (1), a top surface of the cover plate (11) is provided with several exhaust holes, the cover plate (11) is provided with several rectangular slots, a strip-shaped plate (12) is rotatably mounted on a left or right side of an inner wall of each rectangular slot of the cover plate (11), a first torsional spring is arranged between each strip-shaped plate (12) and the cover plate (11), and each strip-shaped plate (12) is located on a movement trajectory of a corresponding vertical column (10);
each vertical column (10) is provided with a chamber inside;
a warning assembly is disposed inside each vertical column (10), the warning assembly comprises a conductive block (13), the conductive block (13) is fixed to a bottom end of an inner wall of the vertical column (10), the conductive block (13) is connected to a wire of the redundant power supply (2), a rubber column (14) is slidably mounted on the inner wall of the vertical column (10), a first spring is arranged between the rubber column (14) and the conductive block (13), an LED lamp (15) is fixedly mounted on a top surface of the rubber column (14), a conductive rod (16) penetrates through and is fixedly mounted on a bottom surface of the rubber column (14), the conductive rod (16) is fixedly connected to the LED lamp (15), a heat accumulation prevention device (6) is coupled to a top surface of the rectangular rod (9), and a fire prevention device (7) is coupled to a bottom surface of the rectangular rod (9).

2. The network security appliance based on a redundant power supply according to claim 1, wherein four supporting legs are disposed on a bottom surface of the cabinet (1), a rectangular opening is formed at a bottom part of a front side of the cabinet (1), a cabinet door is hinged to a right part of the front side of the cabinet (1), bottom parts of left and right sides of the cabinet (1) are provided with heat dissipation openings, the bottom part of the left side of the cabinet (1) is provided with a power supply interface, and the bottom surface of the cabinet (1) is provided with two air intake slots.

3. The network security appliance based on a redundant power supply according to claim 2, wherein the heat accumulation prevention device (6) comprises a cross bar (61), the cross bar (61) is fixed to the top surface of the rectangular rod (9), an opposite end of the cross bar (61) penetrates through a fan plate (62) and the fan plate (62) is rotatably mounted on the cross bar (61), the fan plate (62) is disposed in a middle part inside the cabinet (1), rollers (63) are fixed to a rotating shaft of the fan plate (62) at both ends thereof, two U-shaped frames (64) are fixed to a right side of the inner wall of the cabinet (1), and each U-shaped frame (64) is disposed on a left side of a corresponding roller (63).

4. The network security appliance based on a redundant power supply according to claim 3, wherein an outer wall of the fan plate (62) is covered with anti-static coating, an outer wall of each roller (63) is provided with a rubber rough surface, a middle part of a right side of each U-shaped frame (64) is provided with a penetration opening, and a wheel width of the roller (63) is greater than a width of the penetration opening of the U-shaped frame (64).

5. The network security appliance based on a redundant power supply according to claim 4, wherein the heat accumulation prevention device (6) further comprises a half-arc block (65), the half-arc block (65) is fixed to a left side of an inner wall of each U-shaped frame (64), an arc-shaped spring plate (66) is fixed to an opposite face of the half-arc block (65), the arc-shaped spring plate (66) penetrates through the penetration opening of the U-shaped frame (64), a slidable rod (67) is fixed to a left side of the arc-shaped spring plate (66), a vertical strip plate (68) is fixed to the inner wall of the U-shaped frame (64), the slidable rod (67) penetrates through and is slidably connected to the vertical strip plate (68), and a dehumidifying box (69) is fixed to a left side of the slidable rod (67).

6. The network security appliance based on a redundant power supply according to claim 5, wherein the fire prevention device (7) comprises a connection plate (71), the connection plate (71) is fixed to the bottom surface of the rectangular rod (9), an inclined rod (72) is hinged to a front side of the connection plate (71), a U-shaped sliding groove (73) is fixed to a right side of the inner wall of the cabinet (1), front and back sides of the U-shaped sliding groove (73) are each provided with a sliding groove, rubber wheels (74) are rotatably mounted at bottoms of front and back sides of the inclined rod (72), each rubber wheel (74) is rotatably mounted on an inner wall of a corresponding sliding groove of the U-shaped sliding groove (73), a carbon dioxide cartridge (75) is fixedly mounted at a bottom end inside the cabinet (1), three hoses penetrate through and are fixedly disposed on a top surface of the carbon dioxide cartridge (75), three electric spray nozzles (76) penetrate through and are fixedly mounted on a back side of the inclined rod (72), and each electric spray nozzle (76) is fixedly connected to a corresponding hose of the carbon dioxide cartridge (75).

7. The network security appliance based on a redundant power supply according to claim 6, wherein a second torsional spring is arranged between the inclined rod (72) and the connection plate (71), a temperature sensor is mounted on a back side of the inclined rod (72), the U-shaped sliding groove (73) is located on a lower portion inside the cabinet (1), the connection plate (71) is located on a front side of the electric telescopic rod (8), and a bottom part of a right side of the inclined rod (72) is provided with a chamber.

8. The network security appliance based on a redundant power supply according to claim 7, wherein the fire prevention device (7) further comprises a short plate (77), the short plate (77) is rotatably mounted on an upper portion of an inner wall of the chamber of the inclined rod (72), a rectangular box (78) is fixed to a right side of the short plate (77), a long plate (79) is slidably mounted on an inner wall of the rectangular box (78), a second spring is arranged between the long plate (79) and the rectangular box (78), the long plate (79) is rotatably mounted on a right side of an inner wall of the U-shaped sliding groove (73), and a rotating shaft of the long plate (79) is located on a movement trajectory of the inclined rod (72).
